(19) United States
(12) Patent Application Publication
(10) Pub. No.: US 2015/0002209 A1
(43) Pub. Date: Jan. 1, 2015

(54) CIRCUITS FOR SEMICONDUCTOR DEVICE LEAKAGE CANCELLATION

(71) Applicant: QUALCOMM INCORPORATED, San Diego, CA (US)

(72) Inventor: Ramkumar Sivakumar, San Diego, CA (US)

(21) Appl. No.: 13/930,792

(22) Filed: Jun. 28, 2013

(51) Int. Cl. H03K 17/687

(52) U.S. Cl. CPC H03K 17/687
USPC 327/427

(57) ABSTRACT

One feature pertains to a circuit comprising a semiconductor leakage source device and a semiconductor leakage cancellation device that are both coupled to a signal line. The leakage source device generates a leakage current on the signal line, and the leakage cancellation device generates a leakage cancellation current on the signal line. The leakage cancellation device is sized and shaped in relation to the leakage source device such that the leakage cancellation current effectively cancels the leakage current on the signal line. Moreover, the leakage cancellation current cancels the leakage current on the signal line despite variations in at least one of process, temperature, and/or signal line voltages. In one example, the signal line is a virtual ground node of a capacitive feedback amplifier and the leakage source device is a switch between the virtual ground node and a first terminal of a feedback capacitor of the amplifier.

### BACKGROUND

1. Field

Various features relate to semiconductor devices, and in particular, to circuits for semiconductor device leakage cancellation.

2. Background

FIG. 1 illustrates a schematic block diagram of a programmable gain amplifier (PGA) 100 found in the prior art. The PGA 100 includes an operational amplifier (op-amp) 102, input capacitor C₁, feedback capacitors C₁₁, C₂₁, C₃₁, feedback resistor R, and a plurality of switches S₁₁, S₁₂, S₁₃, S₂₁, S₂₂, S₂₃, S₃₁, S₃₂, S₃₃. The gain of the PGA 100 is given by the ratio between the input capacitor C₁ and the total capacitance between the output node and the virtual ground node. The switches S₁₁, S₁₂, S₂₁, S₂₂, S₃₁, S₃₂ control the amount of capacitance coupled between the aforementioned nodes, and thus, the PGA 100 has a programmable gain depending on which capacitors C₁₁, C₂₁, C₃₁ have been enabled by the switches S₁₁, S₁₂, S₂₁, S₂₂, S₃₁, S₃₂. The PGA 100 shown may be implemented, for example, in a high impedance analog front end of a system, such as the front end for an audio codec.

For various reasons care must be taken when designing the PGA 100 for single ended input signals since the voltage at the virtual ground node will swing during PGA 100 operation. Since the PGA 100 shown is single ended, the common-mode voltage (V_{CM}) of the PGA 100 must be set. The V_{CM} may be set at half the supply voltage (i.e., V_{DD}/2) so that the voltage swing at the virtual ground node allows for voltage headroom for the tail current source (not shown) and the input transistor pair (not shown) of the operational amplifier's 102 first stage. However, in practical implementations the switches S₁₁, S₁₂, S₂₁, S₂₂, S₃₁, S₃₂ will have leakage currents associated with them when the switches are OFF (i.e., switches are open circuit). The resulting total leakage current will cause the common mode voltage V_{CM} to drift because the leakage current flows through the resistor R, which results in a voltage change pursuant to Ohm's Law. This common mode voltage drift may cause the V_{CM} to drift dramatically away from its ideal voltage level of V_{DD}/2, which may in turn cause, among other things, non-linearities in the performance of the PGA 100.

Thus, minimizing or eliminating the aforementioned leakage currents associated with the switches would improve performance of the PGA by, among other things, stabilizing the common mode voltage V_{CM}. Therefore, there generally exists a need to minimize leakage currents associated with semiconductor devices. And in particular there is a need to minimize leakage currents associated with switches (e.g., complementary metal-oxide-semiconductor or CMOS switches) in order to reduce the common mode voltage drift of a PGA and improve performance of a high impedance analog front end employing such a PGA.

### SUMMARY

One feature of the disclosure provides a circuit comprising a semiconductor leakage source device that generates a leakage current on a signal line coupled to the leakage source device. The circuit further comprises a semiconductor leakage cancellation device coupled to the signal line, where the leakage cancellation device is sized and shaped in relation to the leakage source device to generate a leakage cancellation current that effectively cancels the leakage current on the signal line. According to one aspect, the semiconductor leakage cancellation device is adapted to generate the leakage cancellation current that effectively cancels the leakage current on the signal line despite variations in at least one of process, temperature, and/or signal line voltages. According to another aspect, the signal line is a virtual ground node of an amplifier. According to yet another aspect, the amplifier is a capacitive feedback amplifier and the semiconductor leakage source device is a switch between the virtual ground node and a first terminal of a feedback capacitor of the amplifier.

According to one aspect, the semiconductor leakage source device includes a first p-n junction that is reverse biased to generate the leakage current, the semiconductor leakage cancellation device includes a second p-n junction that is reverse biased to generate the leakage cancellation current, and the second p-n junction is sized and shaped in relation to the first p-n junction to generate the leakage cancellation current. According to another aspect, the semiconductor leakage source device includes a first transistor having a first body terminal and a first source/drain terminal, the leakage current including a first leakage current flowing between the first body terminal and the first source/drain terminal, the first source/drain terminal coupled to the signal line, and the semiconductor leakage cancellation device includes a second transistor having a second body terminal and a second source/drain terminal, the second body terminal coupled to the signal line, the leakage cancellation current including a first leakage cancellation current flowing between the second source/drain terminal and the second body terminal, the first leakage cancellation current effectively canceling the first leakage current. According to yet another aspect, a size and shape of the second transistor is equal to a size and shape of the first transistor.

According to one aspect, a signal line voltage V_{SL} at the signal line is equal to V_{DD}/f, where V_{DD} is a supply voltage of the circuit and f is greater than one (1). According to another aspect, an area of the second transistor is equal to |f−1| times an area of the first transistor. According to yet another aspect, a width of the second transistor is equal to |f−1| times a width of the first transistor.

According to one aspect, the first transistor is a first p-channel metal-oxide-semiconductor (PMOS) transistor and the second transistor is a second PMOS transistor, the first body terminal of the first PMOS transistor coupled to V_{DD} and the second source/drain terminal of the second PMOS transistor coupled to V_{SS}, where V_{DD} is a supply voltage of the circuit and V_{SS} is a ground of the circuit. According to another aspect, the first transistor is a first n-channel metal-oxide-semiconductor (NMOS) transistor and the second transistor is a second NMOS transistor, the first body terminal of the first NMOS transistor coupled to V_{SS} and the second source/drain terminal of the second NMOS transistor coupled to V_{DD}, where V_{DD} is a supply voltage of the circuit and V_{SS} is a ground of the circuit. According to yet another aspect, the semiconductor leakage source device further includes a first PMOS transistor having a third body terminal and a third source/drain terminal, the leakage current further including a second leakage current flowing between the third body terminal and the third source/drain terminal, the third source/drain terminal coupled to the signal line, and the semiconductor leakage cancellation device further includes a second PMOS transistor having a fourth body terminal and a fourth source/drain terminal, the fourth body terminal coupled to the signal line, the leakage cancellation current further including a second leakage cancellation current flowing between the fourth source/drain terminal and the fourth body terminal, the second leakage cancellation current effectively canceling the second leakage current.

Another feature of the disclosure provides a method of manufacturing a circuit that comprises forming a signal line, providing a semiconductor leakage source device that generates a leakage current on the signal line, coupling the leakage source device to the signal line, providing a semiconductor leakage cancellation device, coupling the leakage cancellation device to the signal line, and sizing the leakage cancellation device in relation to the leakage source device to generate a leakage cancellation current that effectively cancels the leakage current on the signal line. According to one aspect, the method further comprises providing a feedback capacitor having a first terminal, and wherein the signal line is a virtual ground node of a capacitive feedback amplifier and the semiconductor leakage source device is a switch between the virtual ground node and the first terminal of the feedback capacitor of the amplifier. According to another aspect, the semiconductor leakage source device includes a first p-n junction and the semiconductor leakage cancellation device includes a second p-n junction, and the method further comprises reverse biasing the first p-n junction to generate the leakage current, reverse biasing the second p-n junction to generate the leakage cancellation current, and sizing the second p-n junction in relation to the first p-n junction to generate the leakage cancellation current. According to yet another aspect, the method further comprises providing a first transistor having a first body terminal and a first source/drain terminal, the semiconductor leakage source device including the first transistor, coupling the first source/drain terminal to the signal line, providing a second transistor having a second body terminal and a second source/drain terminal, the semiconductor leakage cancellation device including the second transistor, coupling the second source/drain terminal to the signal line, and wherein the leakage current includes a first leakage current that flows between the first body terminal and the first source/drain terminal, and the leakage cancellation current includes a first leakage cancellation current that flows between the second source/drain terminal and the second body terminal, the first leakage cancellation current is adapted to effectively cancel the first leakage current.

According to one aspect, the method further comprises establishing a signal line voltage V_{SL} at the signal line equal to V_{DD}/f where V_{DD} is a supply voltage of the circuit and f is greater than one (1), and sizing the second transistor so that an area of the second transistor is equal to |f−1| times an area of the first transistor. According to another aspect, the first transistor is a first NMOS transistor and the second transistor is a second NMOS transistor, and the method further comprises coupling the first body terminal of the first NMOS transistor to V_{SS}, and coupling the second source/drain terminal of the second NMOS transistor to V_{DD}, where V_{DD} is a supply voltage of the circuit and V_{SS} is a ground of the circuit. According to yet another aspect, the method further comprises providing a first PMOS transistor having a third body terminal and a third source/drain terminal, coupling the third source/drain terminal to the signal line, providing a second PMOS transistor having a fourth body terminal and a fourth source/drain terminal, coupling the fourth body terminal to the signal line, and wherein the leakage current further includes a second leakage current flowing between the third body terminal and the third source/drain terminal, and the leakage cancellation current further includes a second leakage cancellation current flowing between the fourth source/drain terminal and the fourth body terminal, and the second leakage cancellation current effectively cancels the second leakage current.

Another feature of the disclosure provides a circuit comprising a means for generating a leakage current on a signal line, and a means for generating a leakage cancellation current on the signal line, where the means for generating the leakage current and the means for generating the leakage cancellation current are both coupled to the signal line. The means for generating the leakage cancellation current is sized in relation to the means for generating the leakage current to generate the leakage cancellation current that effectively cancels the leakage current. According to one aspect, the means for generating the leakage cancellation current is adapted to generate the leakage cancellation current that effectively cancels the leakage current on the signal line despite variations in at least one of process, temperature, and/or signal line voltages. According to another aspect, the signal line is a virtual ground node of an amplifier. According to yet another aspect, the amplifier is a capacitive feedback amplifier and the means for generating the leakage current is a switch between the virtual ground node and a first terminal of a feedback capacitor of the amplifier.

According to one aspect, the means for generating the leakage current includes a first p-n junction that is reverse biased to generate the leakage current, the means for generating the leakage cancellation current includes a second p-n junction that is reverse biased to generate the leakage cancellation current, and the second p-n junction is sized and shaped in relation to the first p-n junction to generate the leakage cancellation current. According to another aspect, the means for generating the leakage current includes a first transistor having a first body terminal and a first source/drain terminal, the leakage current including a first leakage current flowing between the first body terminal and the first source/drain terminal, the first source/drain terminal coupled to the signal line, and the means for generating the leakage cancellation current includes a second transistor having a second body terminal and a second source/drain terminal, the second body terminal coupled to the signal line, the leakage cancellation current including a first leakage cancellation current flowing between the second source/drain terminal and the second body terminal, the first leakage cancellation current effectively canceling the first leakage current.

According to one aspect, the means for generating the leakage current further includes a first PMOS transistor having a third body terminal and a third source/drain terminal, the leakage current further including a second leakage current flowing between the third body terminal and the third source/drain terminal, the third source/drain terminal coupled to the signal line, and the means for generating the leakage cancellation current further includes a second PMOS transistor having a fourth body terminal and a fourth source/drain terminal, the fourth body terminal coupled to the signal line, the leakage cancellation current further including a second leakage cancellation current flowing between the fourth source/drain terminal and the fourth body terminal, the second leakage cancellation current effectively canceling the second leakage current.

### BRIEF DESCRIPTION OF THE DRAWINGS

FIG. 1 illustrates a schematic block diagram of a programmable gain amplifier (PGA) found in the prior art.

FIG. 2 illustrates a portion of a first exemplary circuit that includes a leakage source device/circuit and a leakage cancellation device/circuit according to one aspect of the disclosure.

FIG. 3 illustrates an example of the first exemplary circuit in FIG. 2 in which each of the leakage source circuit and the leakage cancellation circuit may include multiple devices.

FIG. 4 illustrates a portion of a second exemplary circuit that includes a leakage source device and a leakage cancellation device according to one aspect of the disclosure.

FIG. 5 illustrates a portion of a third exemplary circuit that includes a leakage source device and a leakage cancellation device according to one aspect of the disclosure.

FIG. 6 illustrates a portion of a fourth exemplary circuit that includes a leakage source circuit and a leakage cancellation circuit according to one aspect of the disclosure.

FIG. 7 illustrates a schematic block diagram representation of the circuits of FIG. 6 using diodes to represent p-n junctions at which leakage currents and leakage cancellation currents flow through.

FIG. 8 illustrates a method of manufacturing an integrated circuit that includes a leakage cancellation device.

FIG. 9 illustrates various electronic devices that may include an integrated circuit according to one aspect of the disclosure.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “source/drain” terminal of a transistor may be either the source or the drain of the transistor. Whether it is actually the source or the drain depends on the voltages applied to the various terminals of the transistor when it is in operation. Moreover, the term “V_{DD}” represents the circuit's power supply voltage, and “V_{SS}” represents the circuit ground.

### Overview

One feature pertains to a circuit comprising a semiconductor leakage source device and a semiconductor leakage cancellation device that are both coupled to a signal line. The leakage source device generates a leakage current on the signal line, and the leakage cancellation device generates a leakage cancellation current on the signal line. The leakage cancellation device is sized and shaped in relation to the leakage source device such that the leakage cancellation current effectively cancels the leakage current on the signal line. Moreover, the leakage cancellation current cancels the leakage current on the signal line despite variations in at least one of process, temperature, and/or signal line voltages. In one example, the signal line is a virtual ground node of a capacitive feedback amplifier and the leakage source device is a switch between the virtual ground node and a first terminal of a feedback capacitor of the amplifier.

### Exemplary Leakage Cancellation Devices and Circuits

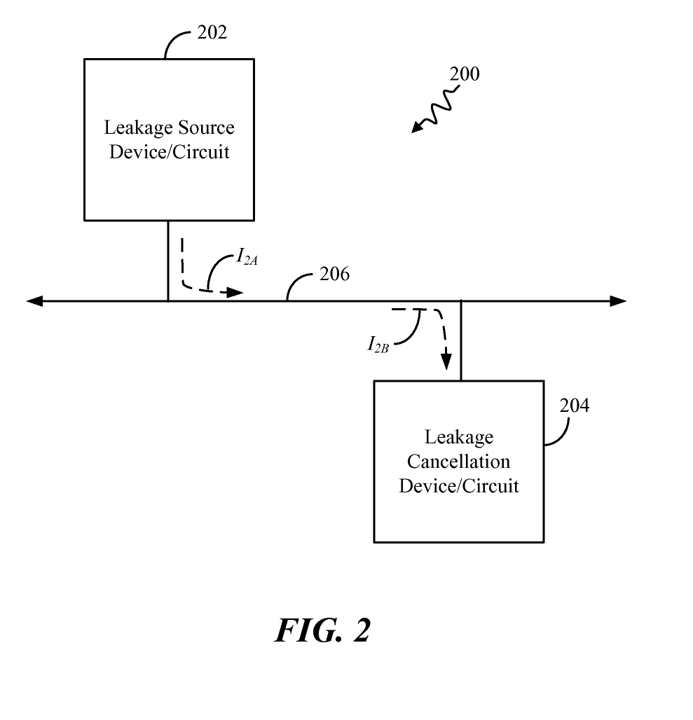

FIG. 2 illustrates a portion of a circuit 200 that includes a leakage source device/circuit 202 and a leakage cancellation device/circuit 204 according to one aspect of the disclosure. The leakage source device/circuit 202 may be one example of a means for generating a leakage current, and the leakage cancellation device/circuit 204 may be one example of a means for generating a leakage cancellation current. Both devices/circuits 202, 204 are coupled to a signal line 206 associated with the circuit 200 (e.g., the signal line 206 is coupled to other circuit components and devices (not shown) of the circuit 200). The leakage source device/circuit 202 is a semiconductor device, such as, but not limited to one or more transistors, diodes, and/or switches. During one or more modes of operation, the leakage source device/circuit 202 injects a leakage current I_{2A} onto the signal line 206. The leakage current I_{2A} may have an undesirable effect on the performance of the circuit 200 (e.g., power consumption, noise, nonlinear performance, etc.), and thus minimizing or eliminating the leakage current I_{2A} is desirable.

The leakage cancellation device/circuit 204 is a semiconductor device that is sized, shaped, and formed using materials (e.g., type of semiconductors used, doping concentrations, etc.) such that it produces a leakage cancellation current I_{2B} that is equal in magnitude to I_{2A} but flows out of the signal line 206. Thus, the same amount of current injected onto the signal line 206 by the leakage source device/circuit 202 is removed from the signal line 206 and the net leakage current remaining on the signal line 206 (e.g., flowing to other portions of the circuit 200) is effectively eliminated/canceled (e.g., shunted away). The size/shape (e.g., width, length, channel length, etc.), materials (e.g., semiconductor type, doping concentrations), and terminal voltages of the leakage cancellation device/circuit 204 may be matched to the leakage source device/circuit 202 so that the leakage cancellation current I_{2B} tracks and cancels the leakage current I_{2A} across process, voltage, and temperature (PVT) changes.

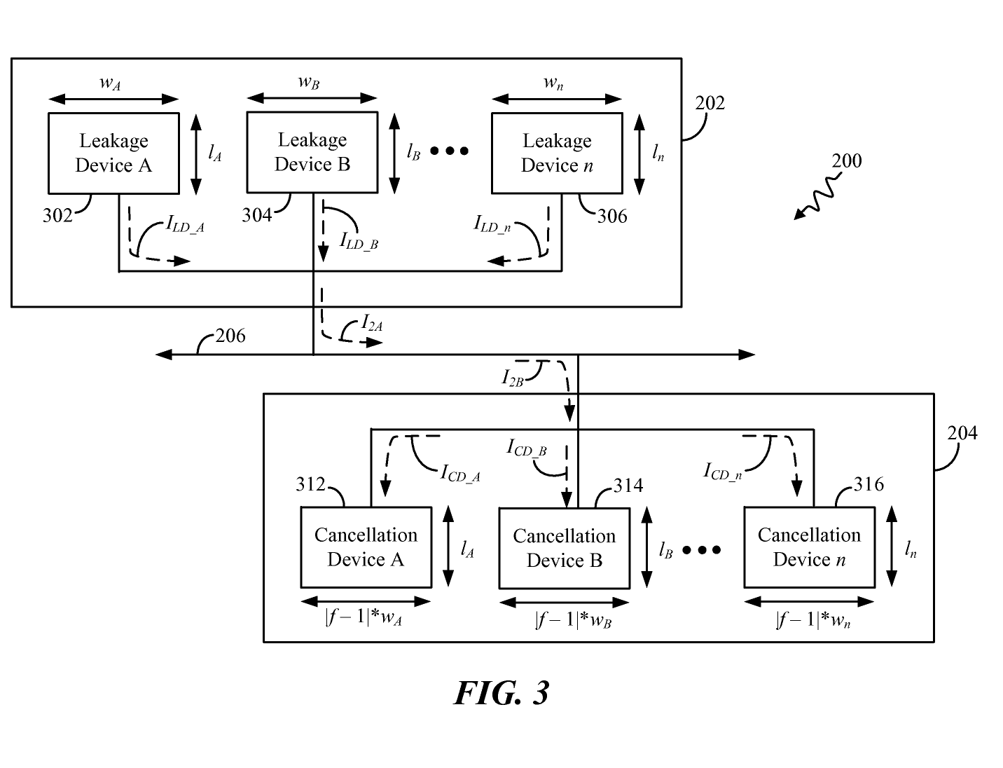

FIG. 3 illustrates the circuit 200 that includes the leakage source circuit 202 and the leakage cancellation circuit 204 according to one aspect of the disclosure. In the illustrated example, the leakage source device/circuit 202 includes a plurality of n leakage source devices 302, 304, 306 where n is an integer greater than one (1). The leakage source devices 30, 304, 306 may be one example of a means for generating a leakage current. Each leakage source device 302, 304, 306 has an associated device width w, device length l, and device area (w*l). For example, leakage source device A 302 has a width w_{A}, length l_{A}, and area (w_{A}*l_{A}), and leakage source device B 304 has a width w_{B}, length l_{B}, and area (w_{B}*l_{B}). Each leakage source device 302, 304, 306 also contributes a leakage current I_{LD}_{_{—}}_{A}, I_{LD}_{_{—}}_{B}, . . . I_{LD}_{_{—}}ₙ. These individual leakage currents add up to the total leakage source current I_{2A}. Although in the example shown all the leakage currents I_{LD}_{_{—}}_{A}, I_{LD}_{_{—}}_{B}, . . . I_{LD}_{_{—}}ₙ are oriented in the same direction (i.e., flowing into the signal line 206), in some aspects one or more of these leakage currents I_{LD}_{_{—}}_{A}, I_{LD}_{_{—}}_{B}, . . . I_{LD}_{_{—}}ₙ may be oriented in the opposite direction (i.e., flowing out of the signal line 206).

Similarly, the leakage cancellation device/circuit 204 includes a plurality of n leakage cancellation devices 312, 314, 316 where n is an integer greater than one (1). The leakage cancellation devices 312, 314, 316 may be one example of a means for generating a leakage cancellation current. Each leakage cancellation device 312, 314, 316 has an associated device width, length, and area. Moreover, each leakage cancellation device 312, 314, 316 also generates a leakage cancellation current I_{CD}_{_{—}}_{A}, I_{CD}_{_{—}}_{B}, . . . I_{CD}_{_{—}}ₙ. These individual leakage cancellation currents add up to the total leakage cancellation current I_{2B}. Although in the example shown all the leakage cancellation currents I_{CD}_{_{—}}_{A}, I_{CD}_{_{—}}_{B}, . . . I_{CD}_{_{—}}ₙ are oriented in the same direction (i.e., flowing out of the signal line 206), in some aspects one or more of these leakage currents I_{CD}_{_{—}}_{A}, I_{CD}_{_{—}}_{B}, . . . I_{CD}_{_{—}}ₙ may be oriented in the opposite direction (i.e., flowing into the signal line 206).

Notably, the leakage cancellation devices 312, 314, 316 are sized and shaped (e.g., device width, length, and/or area is varied) so that each leakage cancellation current I_{CD}_{_{—}}_{A}, I_{CD}_{_{—}}_{B}, . . . I_{CD}_{_{—}}ₙ effectively cancels a corresponding leakage current I_{LD}_{_{—}}_{A}, I_{LD}_{_{—}}_{B}, . . . I_{LD}_{_{—}}ₙ (e.g., shunts the leakage currents I_{LD}_{_{—}}_{A}, I_{LD}_{_{—}}_{B}, . . . I_{LD}_{_{—}}ₙ to ground). For example, leakage cancellation device A 312 may be sized and shaped to generate a leakage cancellation current I_{CD}_{_{—}}_{A} that effectively cancels the leakage current I_{LD}_{_{—}}_{A} contributed by leakage device A 302. Similarly, leakage cancellation device B 314 may be sized and shaped to generate a leakage cancellation current I_{CD}_{_{—}}_{B} that effectively cancels the leakage current I_{LD}_{_{—}}_{B} contributed by leakage device B 304.

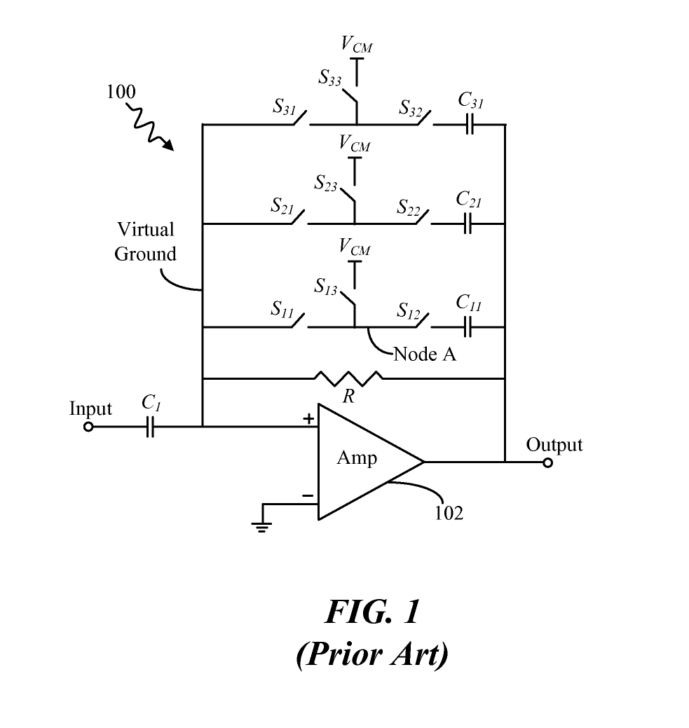

The leakage cancellation devices 312, 314, 316 may be sized in relation to the leakage devices 302, 304, 306 depending on the signal line voltage V_{SL} present at the signal line 206. In some cases this signal line voltage V_{SL} may be the common mode voltage V_{CM} at a virtual ground node of a circuit, such as the PGA 100 shown in FIG. 1. For example, the circuit 200 may have a signal line voltage V_{SL} equal to V_{DD}/f, where factor f is a value greater than one (1). Then, as a general example, leakage cancellation device A 312 may be sized such that its device area (i.e., width times length) is equal to |f−1|*w_{A}*I_{A}, where w_{A} and l_{A} are the width and length of the leakage device A 302, respectively. As one specific example, such as the one shown in FIG. 3, the leakage cancellation device A 312 may be sized such that its device width is equal to |f−1|*W_{A}, and its device length is equal to l_{A}. Thus, as one example, if V_{SL} is equal to V_{DD}/2 then the leakage cancellation devices 312, 314, 316 are sized so that they have the same device area as the leakage devices 302, 304, 306.

In some cases the ratio of the width to length of the leakage cancellation device 312 may be sized such that it is equal to |f−1|*(w_{A}/l_{A}). In such a case both the width and the length of the leakage cancellation device 312 may be sized in relation to the leakage device 302. The other leakage cancellation devices 314, 316 may be sized in a similar fashion so that their width/length ratio corresponds to leakage source devices 304, 306.

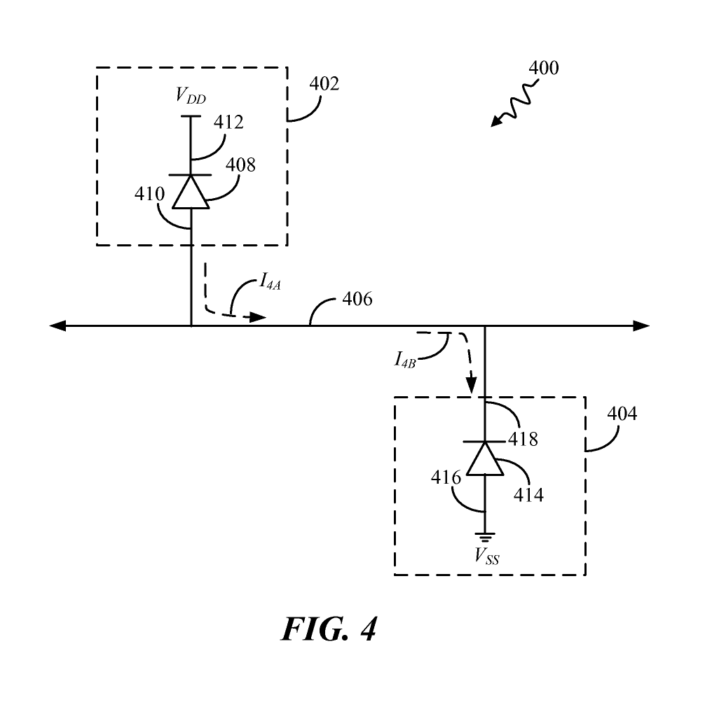

FIG. 4 illustrates a portion of a circuit 400 that includes a leakage source device 402 and a leakage cancellation device 404 according to one aspect of the disclosure. Both devices 402, 404 are coupled to a signal line 406 associated with the circuit 400 (e.g., the signal line 406 is coupled to other circuit components and devices (not shown) of the circuit 400). In the illustrated example, the leakage source device 402 comprises a leakage source diode 408 having an anode 410 coupled to the signal line 406 and a cathode 412 coupled to V_{DD}. As such, the diode 408 is reverse biased (assuming that the signal line voltage V_{SL} is less than V_{DD} and also V_{DD}−V_{SL} is less than the breakdown voltage V_{BR} of the diode 408) and thus a leakage current I_{4A} will flow from the cathode 412 (i.e., from V_{DD}), through the anode 410, and into the signal line 406. The leakage source diode 408 may be one example of a means for generating a leakage current.

The leakage cancellation device 404 comprises a leakage cancellation diode 414 having an anode 416 coupled to ground and a cathode 418 coupled to the signal line 406. As such, the diode 414 is reverse biased (assuming the voltage difference between V_{SL} and ground is less than the breakdown voltage V_{BR} of the diode 414) and thus a leakage cancellation current I_{4B} will flow from the signal line 406, through the cathode 418, and then to the anode 416 (i.e., ground). Notably, if the diode 414 is sized, shaped, and formed appropriately the magnitude of the leakage cancellation current |I_{4B}| can be matched to the magnitude of the leakage current |I_{4A}|. The orientation and device terminal 416, 418 voltages of the diode 414 cause the leakage cancellation current I_{4B} to flow out of the signal line 406 rather than into it like I_{4A}, and thus, the leakage cancellation diode 414 effectively shunts the leakage current I_{4A} to ground. The leakage cancellation diode 414 may be one example of a means for generating a leakage cancellation current.

Assuming the circuit 400 is a complementary metal-oxide-semiconductor (CMOS) circuit, the leakage cancellation diode 414 may be formed using the same process, semiconductor type(s), and doping concentrations as the leakage source diode 408. Depending on the voltage V_{SL} at the signal line, the leakage cancellation diode 414 is sized such that its area (e.g., at least one of its width and length (or their ratio)) may be varied so that |I_{4B}|=|I_{4A}|. As one example, if the signal line voltage V_{SL} is V_{DD}/2 then the leakage cancellation diode 414 may be formed such that it is as close to identical (e.g., same size, shape, etc.) as the leakage source diode 408. As another example, if the signal line voltage V_{SL} is V_{DD}/f (where factor f is greater than one (1)), then the device area of the leakage cancellation diode 414 may be |f−1| times the device area of the leakage source diode 408. For example, the leakage cancellation diode's 414 width may be |f−1| times the leakage source diode's 408 width, and the leakage cancellation diode's 414 length may be the same as the leakage source diode's 408 length.

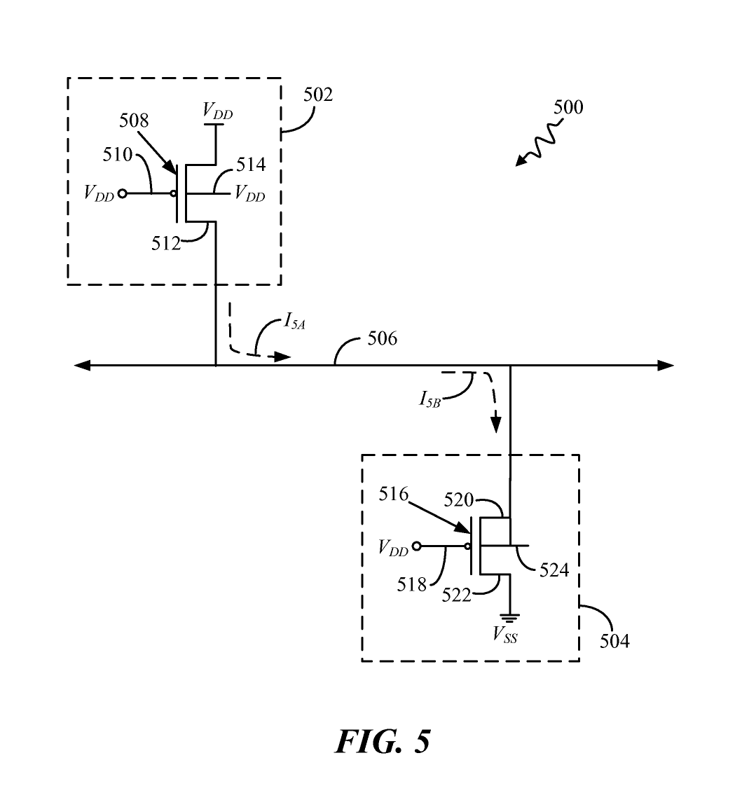

FIG. 5 illustrates a portion of a circuit 500 that includes a leakage source device 502 and a leakage cancellation device 504 according to one aspect of the disclosure. Both devices 502, 504 are coupled to a signal line 506 associated with the circuit 500 (e.g., the signal line 506 is coupled to other circuit components and devices (not shown) of the circuit 500). In the illustrated example, the leakage source device 502 comprises a PMOS transistor 508 having a gate 510 coupled to V_{DD}, a first source/drain 512 coupled to the signal line 506, and a body 514 also coupled to V_{DD}. As such, the leakage source transistor 508 is OFF, and a leakage current I_{5A} will flow into the signal line 506 from the body 514 (e.g., through the reverse biased p-n junction at the interface between the body 514 and the first source/drain 512) assuming the signal line voltage V_{SL} is less than V_{DD}. The leakage source transistor 508 may be one example of a means for generating a leakage current.

The leakage cancellation device 504 also comprises a PMOS transistor 516. The leakage cancellation transistor 516 has a gate 518 coupled to V_{DD}, a first source/drain 520 and a body 524 both coupled to the signal line 506, and a second source/drain 522 coupled to ground. As such, the leakage cancellation transistor 516 is OFF, and a leakage cancellation current I_{5B} will flow from the signal line 506, through the body 524, and eventually to ground (i.e., second source/drain 522). Notably, if the leakage cancellation transistor 516 is sized, shaped, and formed appropriately the magnitude of the leakage cancellation current |I_{5B}| can be matched to the magnitude of the leakage current |I_{5A}|. The orientation and device terminal 518, 520, 522, 524 connections of the leakage cancellation transistor 516 cause the leakage cancellation current I_{5B} to flow out of the signal line 506 rather than into it like the current I_{SA}, and thus, the transistor 516 effectively shunts the leakage current I_{SA} to ground. The leakage cancellation transistor 516 may be one example of a means for generating a leakage cancellation current.

Assuming the circuit 500 is a CMOS circuit, the leakage cancellation transistor 516 may be formed using the same process, semiconductor types, and doping concentrations as the leakage source transistor 508. Depending on the voltage V_{SL} at the signal line, the leakage cancellation transistor 516 is sized such that its area (e.g., at least one of its width and length (or their ratio)) may be varied so that |I_{5B}|=|I_{5A}|. As one example, if the signal line voltage V_{SL} is V_{DD}/2 then the leakage cancellation transistor 516 may be formed such that it is as close to identical (e.g., same size, shape, etc.) as the leakage source transistor 508. As another example, if the signal line voltage V_{SL} is V_{DD}/f (factor f is greater than one (1)), then the device area of the leakage cancellation transistor 516 may be |f−1| times the device area of the leakage source transistor 508. For example, the leakage cancellation transistor's 516 width may be |f−1| times the leakage source transistor's 508 width, and the leakage cancellation transistor's 516 length may be the same as the leakage source transistor's 508 length.

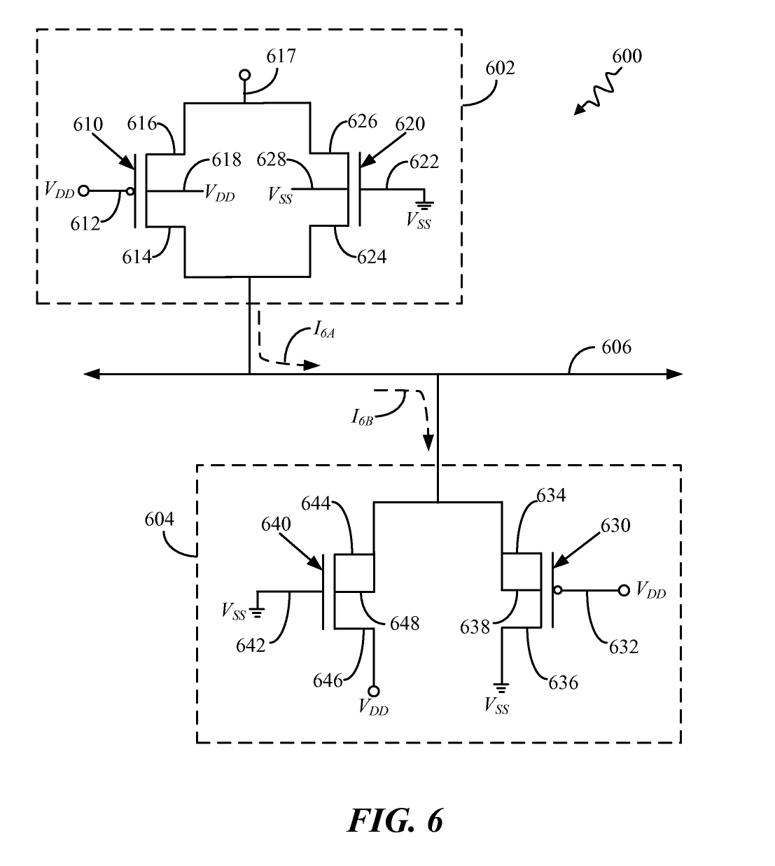

FIG. 6 illustrates a portion of a circuit 600 that includes a leakage source circuit 602 and a leakage cancellation circuit 604 according to one aspect of the disclosure. Both circuits 602, 604 are coupled to a signal line 606 associated with the circuit 600, and the signal line 606 is coupled to other circuit components and devices. Referring to FIGS. 1 and 6, according to one aspect of the disclosure, the aforementioned other circuit components and devices coupled to the signal line 606 may be the PGA circuit 100. In such a case, the signal line 606 of FIG. 6 is the virtual ground node of FIG. 1, and the leakage source circuit 602 is a CMOS switch (e.g., switch S₁₁).

The CMOS switch 602 comprises a p-channel metal-oxide-semiconductor (PMOS) transistor 610 and an n-channel metal-oxide-semiconductor (NMOS) transistor 620. The PMOS transistor 610 includes a gate 612 coupled to V_{DD}, a first source/drain 614 coupled to the signal line 606, a second source/drain 616 coupled to a node 617 (e.g., node 617 may be node A shown in FIG. 1), and a body 618 coupled to V_{DD}. The NMOS transistor 620 includes a gate 622 coupled to V_{SS}, a first source/drain 624 coupled to the signal line 606, a second source/drain 626 coupled to the node 617, and a body 628 also coupled to V_{SS}. As such, the PMOS transistor 610 is OFF and a leakage current will flow from the body 618 to the signal line 606 (e.g., through the reverse biased p-n junction at the interface between the body 618 and the first source/drain 614) assuming the signal line voltage V_{SL} is less than V_{DD}. Similarly, the NMOS transistor 620 is OFF and a leakage current will flow into the body 628 from the signal line 606 (e.g., through the reverse biased p-n junction at the interface between the first source/drain 624 and the body 628) assuming the signal line voltage V_{SL} is greater than V_{SS}. In the illustrated example, a net leakage current I_{6A} flows into the signal line 606 from the PMOS transistor's body 618. However, in other examples, the net leakage current I_{6A} may flow in an opposite direction if the leakage current associated with the NMOS transistor 620 is greater than the leakage current associated with the PMOS transistor 610. The switch 602 (e.g., leakage source transistors 610, 620) may be one example of a means for generating a leakage current.

The leakage cancellation circuit 604 comprises a PMOS transistor 630 and an NMOS transistor 640. The PMOS transistor 630 includes a gate 632 coupled to V_{DD}, a first source/drain 634 coupled to the signal line 606, a second source/drain 636 coupled to ground, and a body 638 also coupled to the signal line 606. The NMOS transistor 640 includes a gate 642 coupled to V_{SS}, a first source/drain 644 coupled to the signal line 606, a second source/drain 646 coupled to V_{DD}, and a body 648 also coupled to the signal line 606. As such, a leakage cancellation current will flow from the signal line 606, through the PMOS transistor's body 638, and then to ground (i.e., to the second source/drain 636). Similarly, a leakage cancellation current will flow from the supply voltage V_{DD}, through the NMOS transistor's body 648, and into the signal line 606. The resulting net leakage cancellation current I_{6B} associated with the leakage cancellation circuit 604 effectively cancels the leakage current generated by the leakage source circuit 602 (e.g., the switch S₁₁). The leakage cancellation transistors 630, 640 may be one example of a means for generating a leakage cancellation current.

In the illustrated example, the net leakage cancellation current I_{6B} of the leakage cancellation circuit 604 flows from the signal line 606 to ground (i.e., the second source/drain 636 of the PMOS transistor 630) because the leakage current I_{6A} flows into the signal line 606, and the leakage cancellation circuit 604 is designed to shunt that current I_{6A} to ground. According to another example, if instead the leakage current I_{6A} flowed from the signal line 606 and into the switch 602 (e.g., into the switch NMOS transistor's body 628), then the orientation of the leakage cancellation current I_{6B} would be reversed so that it flowed into the signal line 606 from the leakage cancellation NMOS transistor's body 648.

The leakage cancellation PMOS transistor 630 is sized, shaped, and formed so that its leakage cancellation current is equal to the magnitude of the leakage current associated with the switch's PMOS transistor 610. Similarly, the leakage cancellation NMOS transistor 640 is sized, shaped, and formed so that its leakage cancellation current is equal to the magnitude of the leakage current associated with the switch's NMOS transistor 620.

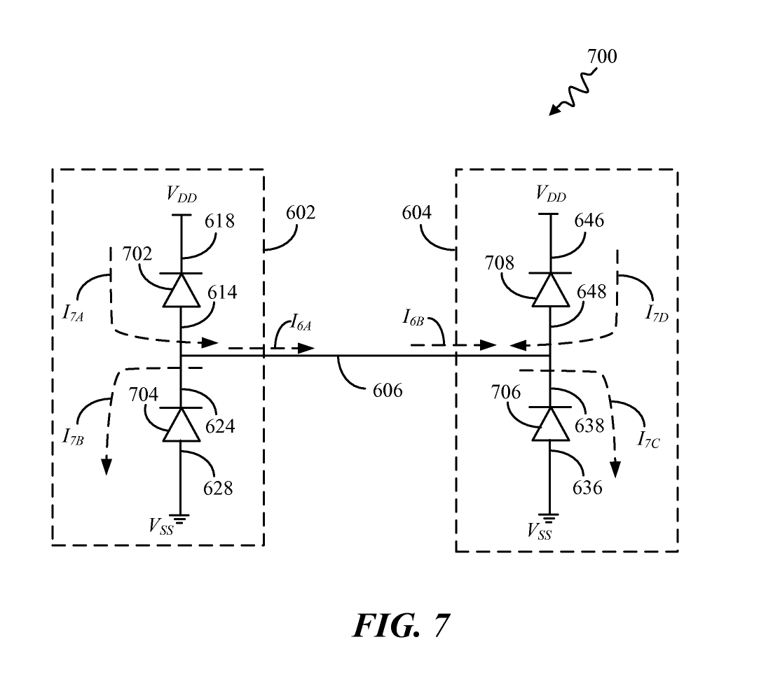

The aforementioned leakage currents associated with the leakage source transistors 610, 620 and the leakage cancellation currents associated with the leakage cancellation transistors 630, 640 are simplified and represented by the schematic block diagram 700 shown in FIG. 7. FIG. 7 represents the p-n junctions at which these leakage currents and leakage cancellation currents flow through using diodes 702, 704, 706, 708. Specifically, the first diode 702 represents the p-n junction between the switch PMOS transistor's body 618 and first source/drain 614. A leakage current I_{7A} flows from its body 618 to its first source/drain 614. The second diode 704 represents the p-n junction between the switch NMOS transistor's body 628 and first source/drain 624. A leakage current I_{7B} flows from its first source/drain 624 to its body 628. In the given example, these leakage currents flow in opposite directions and thus the magnitude of the net leakage source current I_{6A} is equal to the difference between these currents |I_{7A}−I_{7B}|. The third diode 706 represents the p-n junction between the leakage cancellation circuit PMOS transistor's body 638 and second source/drain 636. A leakage current I_{7C} flows from its body 638 to its second source/drain 636. The fourth diode 708 represents the p-n junction between the leakage cancellation circuit NMOS transistor's body 648 and second source/drain 646. A leakage current I_{7D} flows from its second source/drain 646 to its body 648. In the given example, these leakage cancellation currents flow in opposite directions and thus the magnitude net leakage cancellation current I_{6B} is equal to the difference between these currents |I_{7C}−I_{7D}|.

The leakage cancellation PMOS transistor 630 is sized, shaped, and formed so that its leakage cancellation current I_{7C} is equal to the magnitude of the leakage current I_{7A} associated with the switch's PMOS transistor 610. This effectively cancels (e.g., shunts to ground) the leakage current I_{7A}. Similarly, the leakage cancellation NMOS transistor 640 is sized, shaped, and formed so that its leakage cancellation current I_{7D} is equal to the magnitude of the leakage current I_{7B} associated with the switch's NMOS transistor 620. This effectively cancels (e.g., shunts away) the leakage current I_{7B}.

The leakage cancellation PMOS transistor 630 may be fabricated using the same process, semiconductor types, and doping concentrations as the switch PMOS transistor 610. Depending on the voltage V_{SL} at the signal line 606 (e.g., the common mode voltage V_{CM} at the virtual ground node of the PGA 100), the leakage cancellation PMOS transistor 630 is sized such that its area (e.g., at least one of its width and/or length) may be varied so that |I_{7C}|=|I_{7A}|. As one example, if the signal line voltage V_{SL} is V_{DD}/2 (e.g., the desired V_{CM} at virtual ground node is V_{DD}/2), then the leakage cancellation PMOS transistor 630 may be fabricated such that it is as close to identical (e.g., same size, shape, etc.) as the switch PMOS transistor 610. As another example, if the signal line voltage V_{SL} is V_{DD}/f (e.g., desired common mode voltage V_{CM} at virtual ground node is V_{DD}/f) where factor f is greater than one (1), then the device area of the leakage cancellation PMOS transistor 630 may be |f−1| times the device area of the switch PMOS transistor 610. For example, the leakage cancellation PMOS transistor's 630 width may be |f−1| times the switch PMOS transistor's 610 width, and the leakage cancellation PMOS transistor's 630 length may be the same as the switch PMOS transistor's 610 length.

Similarly, the leakage cancellation NMOS transistor 640 may be fabricated using the same process, semiconductor types, and doping concentrations as the switch NMOS transistor 620. Depending on the voltage V_{SL} at the signal line 606 (e.g., the common mode voltage V_{CM} at the virtual ground node of the PGA 100), the leakage cancellation NMOS transistor 640 is sized such that its area (e.g., at least one of its width and/or length) may be varied so that |I_{7D}|=|I_{7B}|. As one example, if the signal line voltage V_{SL} is V_{DD}/2 (e.g., the desired V_{CM} at virtual ground node is V_{DD}/2), then the leakage cancellation NMOS transistor 640 may be fabricated such that it is as close to identical (e.g., same size, shape, etc.) as the switch NMOS transistor 620. As another example, if the signal line voltage V_{SL} is V_{DD}/f (e.g., desired common mode voltage V_{CM} at virtual ground node is V_{DD}/f) where factor f is greater than one (1), then the device area of the leakage cancellation NMOS transistor 640 may be |f−1| times the device area of the switch NMOS transistor 620. For example, the leakage cancellation NMOS transistor's 640 width may be |f−1| times the switch NMOS transistor's 620 width, and the leakage cancellation NMOS transistor's 640 length may be the same as the switch NMOS transistor's 620 length.

In this fashion, the leakage current I_{6A}—that would otherwise flow to other parts of the circuit 600 to which the signal line 606 is connected—is shunted away (e.g., to ground) by the leakage cancellation circuit 604 and effectively canceled. In the example where the signal line 606 is the virtual ground node of a PGA (e.g., PGA 100 in FIG. 1), cancelling the leakage current I_{6A} contributed by the switch 602 significantly reduces or even eliminates the common mode voltage drift of the PGA 100. Each of the switches S₁₁, S₁₂, S₁₃, S₂₁, S₂₂, S₂₃, S₃₁, S₃₂, and/or S₃₃ that may cause such a drift in common mode voltage due to leakage current may be pacified with a separate leakage current cancellation circuit 604 that may be specifically fabricated to match and eliminate the corresponding switch's leakage current contribution.

### Exemplary Method of Manufacturing a Circuit

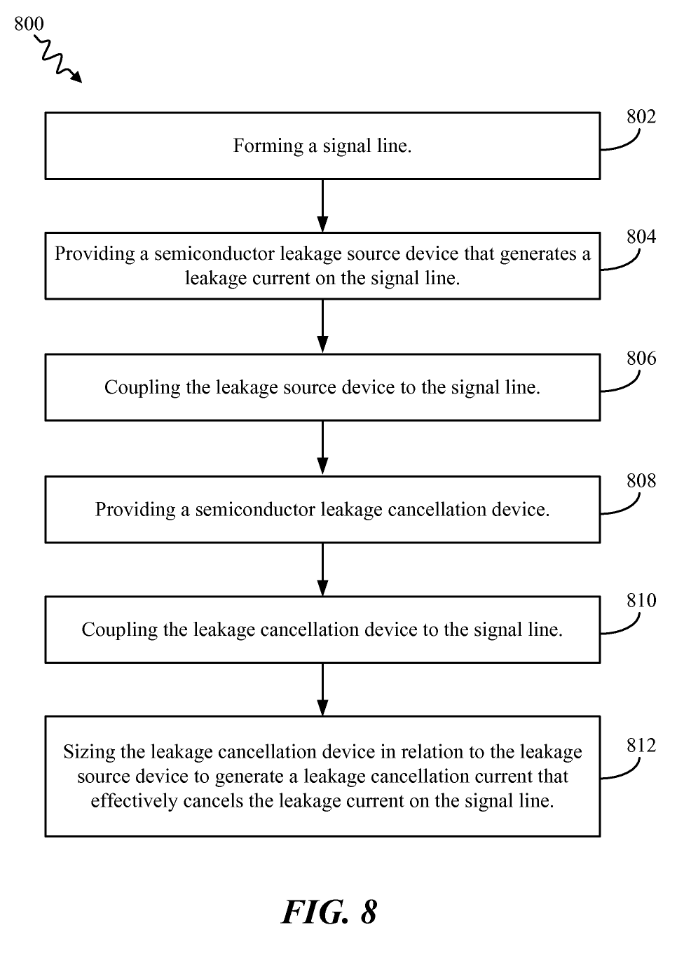

FIG. 8 illustrates a method 800 of manufacturing an integrated circuit according to one aspect. First, a signal line is formed 802. Next, a semiconductor leakage source device is provided that generates a leakage current on the signal line 804. Then, the leakage source device is coupled to the signal line 806. Next, a semiconductor leakage cancellation device is provided 808. Then, the leakage cancellation device is coupled to the signal line 810. Next, the leakage cancellation device is sized and shaped in relation to the leakage source device to generate a leakage cancellation current that effectively cancels the leakage current on the signal line 812.

### Exemplary Devices Featuring Integrated Circuit

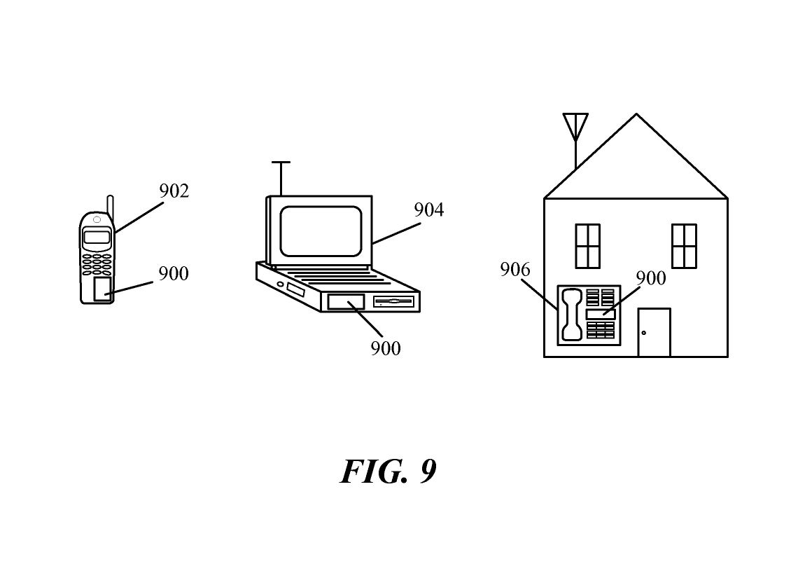

FIG. 9 illustrates various electronic devices that may include an integrated circuit 900 according to one aspect. The integrated circuit 900 may be any one of the integrated circuits 200, 400, 500, 600, 700 described above with respect to FIGS. 2, 3, 4, 5, 6, and/or 7. For example, a mobile telephone 902, a laptop computer 904, and a fixed location terminal 906 may include the integrated circuit 900. The devices 902, 904, 906 illustrated in FIG. 9 are merely exemplary. Other electronic devices may also feature the integrated circuit 1700 including, but not limited to, hand-held personal communication systems (PCS) units, portable data units such as personal data assistants, GPS enabled devices, navigation devices, set top boxes, music players, video players, entertainment units, fixed location data units such as meter reading equipment, or any other device that stores or retrieves data or computer instructions, or any combination thereof.

One or more of the components, steps, features, and/or functions illustrated in FIGS. 1, 2, 3, 4, 5, 6, 7, 8, and/or 9 may be rearranged and/or combined into a single component, step, feature or function or embodied in several components, steps, or functions. Additional elements, components, steps, and/or functions may also be added without departing from the invention.

Also, it is noted that the aspects of the present disclosure may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A circuit comprising:
a semiconductor leakage source device that generates a leakage current on a signal line coupled to the leakage source device; and
a semiconductor leakage cancellation device coupled to the signal line, the leakage cancellation device sized in relation to the leakage source device to generate a leakage cancellation current that effectively cancels the leakage current on the signal line.

2. The circuit of claim 1, wherein the semiconductor leakage cancellation device is adapted to generate the leakage cancellation current that effectively cancels the leakage current on the signal line despite variations in at least one of process, temperature, and/or signal line voltages.

3. The circuit of claim 1, wherein the signal line is a virtual ground node of an amplifier.

4. The circuit of claim 3, wherein the amplifier is a capacitive feedback amplifier and the semiconductor leakage source device is a switch between the virtual ground node and a first terminal of a feedback capacitor of the amplifier.

5. The circuit of claim 1, wherein the semiconductor leakage source device includes a first p-n junction that is reverse biased to generate the leakage current, the semiconductor leakage cancellation device includes a second p-n junction that is reverse biased to generate the leakage cancellation current, and the second p-n junction is sized and shaped in relation to the first p-n junction to generate the leakage cancellation current.

6. The circuit of claim 1, wherein the semiconductor leakage source device includes a first transistor having a first body terminal and a first source/drain terminal, the leakage current including a first leakage current flowing between the first body terminal and the first source/drain terminal, the first source/drain terminal coupled to the signal line, and the semiconductor leakage cancellation device includes a second transistor having a second body terminal and a second source/drain terminal, the second body terminal coupled to the signal line, the leakage cancellation current including a first leakage cancellation current flowing between the second source/drain terminal and the second body terminal, the first leakage cancellation current effectively canceling the first leakage current.

7. The circuit of claim 6, wherein a size and shape of the second transistor is equal to a size and shape of the first transistor.

8. The circuit of claim 6, wherein a signal line voltage V_{SL} at the signal line is equal to V_{DD}/f, where V_{DD} is a supply voltage of the circuit and f is greater than one (1).

9. The circuit of claim 8, wherein an area of the second transistor is equal to |f−1| times an area of the first transistor.

10. The circuit of claim 8, wherein a width of the second transistor is equal to |f−1| times a width of the first transistor.

11. The circuit of claim 6, wherein the first transistor is a first p-channel metal-oxide-semiconductor (PMOS) transistor and the second transistor is a second PMOS transistor, the first body terminal of the first PMOS transistor coupled to V_{DD} and the second source/drain terminal of the second PMOS transistor coupled to V_{SS} where V_{DD} is a supply voltage of the circuit and V_{SS} is a ground of the circuit.

12. The circuit of claim 6, wherein the first transistor is a first n-channel metal-oxide-semiconductor (NMOS) transistor and the second transistor is a second NMOS transistor, the first body terminal of the first NMOS transistor coupled to V_{SS} and the second source/drain terminal of the second NMOS transistor coupled to V_{DD}, where V_{DD} is a supply voltage of the circuit and V_{SS} is a ground of the circuit.

13. The circuit of claim 12, wherein the semiconductor leakage source device further includes a first PMOS transistor having a third body terminal and a third source/drain terminal, the leakage current further including a second leakage current flowing between the third body terminal and the third source/drain terminal, the third source/drain terminal coupled to the signal line, and the semiconductor leakage cancellation device further includes a second PMOS transistor having a fourth body terminal and a fourth source/drain terminal, the fourth body terminal coupled to the signal line, the leakage cancellation current further including a second leakage cancellation current flowing between the fourth source/drain terminal and the fourth body terminal, the second leakage cancellation current effectively canceling the second leakage current.

14. The circuit of claim 1, wherein the circuit is incorporated into at least one of a music player, a video player, an entertainment unit, a navigation device, a communications device, a mobile phone, a smartphone, a personal digital assistant, a fixed location terminal, a tablet computer, and/or a laptop computer.

15. A circuit comprising:
means for generating a leakage current on a signal line; and
means for generating a leakage cancellation current on the signal line, the means for generating the leakage current and the means for generating the leakage cancellation current both coupled to the signal line, and wherein the means for generating the leakage cancellation current is sized in relation to the means for generating the leakage current to generate the leakage cancellation current that effectively cancels the leakage current.

16. The circuit of claim 21, wherein the means for generating the leakage cancellation current is adapted to generate the leakage cancellation current that effectively cancels the leakage current on the signal line despite variations in at least one of process, temperature, and/or signal line voltages.

17. The circuit of claim 21, wherein the signal line is a virtual ground node of an amplifier.

18. The circuit of claim 23, wherein the amplifier is a capacitive feedback amplifier and the means for generating the leakage current is a switch between the virtual ground node and a first terminal of a feedback capacitor of the amplifier.

19. The circuit of claim 21, wherein the means for generating the leakage current includes a first p-n junction that is reverse biased to generate the leakage current, the means for generating the leakage cancellation current includes a second p-n junction that is reverse biased to generate the leakage cancellation current, and the second p-n junction is sized and shaped in relation to the first p-n junction to generate the leakage cancellation current.

20. The circuit of claim 21, wherein the means for generating the leakage current includes a first transistor having a first body terminal and a first source/drain terminal, the leakage current including a first leakage current flowing between the first body terminal and the first source/drain terminal, the first source/drain terminal coupled to the signal line, and the means for generating the leakage cancellation current includes a second transistor having a second body terminal and a second source/drain terminal, the second body terminal coupled to the signal line, the leakage cancellation current including a first leakage cancellation current flowing between the second source/drain terminal and the second body terminal, the first leakage cancellation current effectively canceling the first leakage current.

21. The circuit of claim 26, wherein a signal line voltage V_{SL} at the signal line is equal to V_{DD}/f, where V_{DD} is a supply voltage of the circuit and f is greater than one (1), and an area of the second transistor is equal to |f−1| times an area of the first transistor.

22. The circuit of claim 26, wherein the first transistor is a first p-channel metal-oxide-semiconductor (PMOS) transistor and the second transistor is a second PMOS transistor, the first body terminal of the first PMOS transistor coupled to V_{DD} and the second source/drain terminal of the second PMOS transistor coupled to V_{SS}, where V_{DD} is a supply voltage of the circuit and V_{SS} is a ground of the circuit.

23. The circuit of claim 26, wherein the first transistor is a first n-channel metal-oxide-semiconductor (NMOS) transistor and the second transistor is a second NMOS transistor, the first body terminal of the first NMOS transistor coupled to V_{SS} and the second source/drain terminal of the second NMOS transistor coupled to V_{DD}, where V_{DD} is a supply voltage of the circuit and V_{SS} is a ground of the circuit.

24. The circuit of claim 29, wherein the means for generating the leakage current further includes a first PMOS transistor having a third body terminal and a third source/drain terminal, the leakage current further including a second leakage current flowing between the third body terminal and the third source/drain terminal, the third source/drain terminal coupled to the signal line, and the means for generating the leakage cancellation current further includes a second PMOS transistor having a fourth body terminal and a fourth source/drain terminal, the fourth body terminal coupled to the signal line, the leakage cancellation current further including a second leakage cancellation current flowing between the fourth source/drain terminal and the fourth body terminal, the second leakage cancellation current effectively canceling the second leakage current.

25. The circuit of claim 1, wherein the circuit is incorporated into at least one of a music player, a video player, an entertainment unit, a navigation device, a communications device, a mobile phone, a smartphone, a personal digital assistant, a fixed location terminal, a tablet computer, and/or a laptop computer.
